(19) United States
(12) Patent Application Publication
(10) Pub. No.: US 2022/0225542 A1
(43) Pub. Date: Jul. 14, 2022

(54) THIN FORM FACTOR ASSEMBLIES FOR COOLING DIMMS

(71) Applicant: Intel Corporation, Santa Clara, CA (US)

(72) Inventors: Prabhakar SUBRAHMANYAM, San Jose, CA (US); Yi XIA, Campbell, CA (US); Ying-Feng PANG, San Jose, CA (US); Tong Wa CHAO, San Jose, CA (US); Mark BIANCO, Redwood City, CA (US); Yanbing SUN, Shanghai (CN); Ming ZHANG, Shanghai (CN); Guixiang TAN, Portland, OR (US); Devdatta P. KULKARNI, Portland, OR (US); Guocheng ZHANG, Shanghai (CN); Hao ZHOU, Shanghai (CN)

(21) Appl. No.: 17/710,640

(22) Filed: Mar. 31, 2022

(30) Foreign Application Priority Data
Feb. 25, 2022 (CN) PCTCN2022077904

(51) Int. Cl. H05K 7/20; G11C 5/04

(52) U.S. Cl. CPC H05K 7/20509; G11C 5/04; H05K 7/20709; H05K 7/20436

(57) ABSTRACT

A dual in-line memory module (DIMM) cooling apparatus is described. The DIMM cooling assembly includes a first heat spreader to be thermally coupled to respective memory chips of a first side of the DIMM. The DIMM cooling assembly includes a second heat spreader to be thermally coupled to respective memory chips of a second side of the DIMM. The DIMM cooling assembly includes a heat sink element. The heat sink element is to reside above the DIMM. The heat sink element is to receive heat from the first and second heat spreaders. The heat sink element has thermal transfer structures to lower thermal resistance between the heat sink element and the heat sink element's ambient.

### RELATED APPLICATION

This application claims the benefit of priority to Patent Cooperation Treaty (PCT) Application No. PCT/CN2022/077904 filed Feb. 25, 2022. The entire content of that application is incorporated by reference.

### BACKGROUND

With the emergence of “big data” and high performance, centralized computing (e.g., “cloud computing”), processor and memory chips are being pushed to higher and higher levels of performance. The increased performance translates into increased processor and memory chip heat dissipation.

Heat dissipation with respect to dynamic random access memory (DRAM) dual in-line memory modules (DIMMs) is particularly troublesome because of the small spacing between DIMMs. For example, older technology DDR4 DIMMs tend to consume 4-5 Watts (W) maximum and are commonly spaced 0.8 mm apart, whereas, leading edge DDR5 DIMMs can consume as much as 25 W and can be placed as little as 0.3 mm.

The combination of higher DIMM heat dissipation and smaller air gaps between DIMMs brings DIMM cooling into the forefront of challenges faced by systems designers.

### FIGURES

FIGS. 1a, 1b and 1c show improved DIMM cooling assemblies;

FIGS. 2a, 2b and 2c show improved DIMM cooling assemblies composed of a same bulk material;

FIGS. 3a and 3b show improved DIMM cooling assemblies composed of separate mechanical components;

FIGS. 4a, 4b, 4c and 4d show improved DIMM cooling assemblies having separate heat spreading and heat sink components;

FIGS. 5a and 5b show a cooling assembly for multiple DIMMs with a heat sink structure that is separate from the heat spreading elements;

FIGS. 6a and 6b show thermally conducting pedestals emanating from a heat spreader;

FIGS. 7a and 7b show different approaches for mounting heat spreaders to a DIMM;

FIG. 8 shows a computing system;

FIG. 9 shows a data center;

FIG. 10 shows a rack.

### DETAILED DESCRIPTION

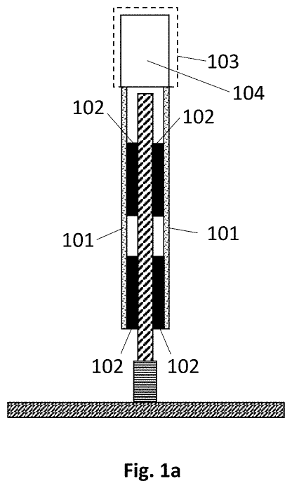

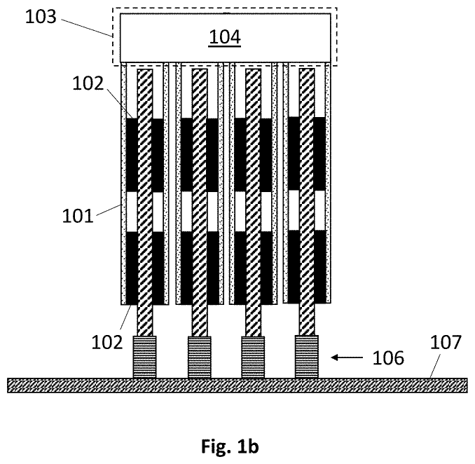

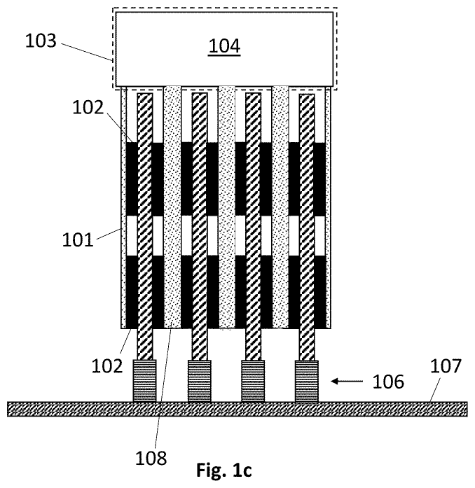

FIG. 1a shows a high level view of a cooling assembly for a DIMM. As observed in FIG. 1a, thermally conductive heat spreaders 101 are thermally coupled to the package lids of the memory chips 102 on both sides of the DIMM. The heat spreaders 101 extend into the space 103 above the DIMM and merge into, and/or are otherwise connected to, a heat sink structure (also referred to as a heat sink element) 104 that resides in the space 103 above the DIMM. The heat spreaders 101 and the heat sink structure 104 are composed of one or more thermally conductive materials such as metals, metal alloys, etc.

Here, heat is transferred from the memory chips 102 to the heat spreaders 101 and then to the heat sink structure 104. The heat sink structure 104 then transfers the heat into the ambient. Air flow can be directed across the heat sink structure 104 to remove the heat from the ambient.

As will be more clear in the following discussion, the heat sink structure 104 can include fins or other heat transferring structures (e.g., posts, fingers, roughened surface structures, etc.) that increase the surface area of the interface between the heat sink structure 104 and the ambient to lower the thermal resistance between the thermally radiant structure 104 and the ambient. Moreover, the heat sink structure 104 can be composed of multiple mechanical components or a single, mechanical component.

Whereas FIG. 1a shows the approach for one DIMM, FIG. 1b shows the approach for a number of DIMMs that are placed in close proximity to one another, such as a bank of DIMMs that are respectively plugged into corresponding DIMM sockets 106 mounted on a printed circuit board 107.

As observed in the embodiment of FIG. 1b, the heat spreaders 101 have a thickness that is less than half the spacing between DIMMs which, in turn, allows the heat spreaders to remain attached to the sides of the DIMMs without touching the respective heat spreaders of neighboring DIMMs. Moreover, the heat spreaders 101 of multiple DIMMs merge into, and/or connected to, a common heat sink structure 104. The common heat sink structure 104 receives heat from multiple DIMMs and transfers heat from the multiple DIMMs.

FIG. 1c shows an approach that is similar to that of FIG. 1b but where a single heat spreader 108 is located between neighboring DIMMs. In the approach of FIG. 1c, the thickness of heat spreaders that resides between neighboring DIMMs have a thickness that is approximately the distance between DIMMs (more specifically, the distance between facing DRAM package lids of neighboring DIMMs) so that the common heat spreader 108 is able to receive heat from the DRAM package lids that is the heat spreader resides between.

In various embodiments, for a row or bank of DIMMs, either the approach of FIG. 1a can be taken or the approaches of FIG. 1b/1c can be taken. With respect the approach of FIG. 1a, each DIMM in the row has its own dedicated heat sink structure 104, whereas, in the approaches of FIG. 1b/1c, the heat sink structure 104 is expanded to be in thermal contact with the respective heat spreaders of multiple DIMMs.

As will be described in more detail below, in various embodiments, the heat sink structure has a significant amount of mass so that it draws heat from the heat spreaders. In other embodiments, the heat sink structure has less mass (e.g., to reduce the weight of the assembly) and emphasizes fins or other surface area expanding structures to more efficiently transfer heat to the ambient.

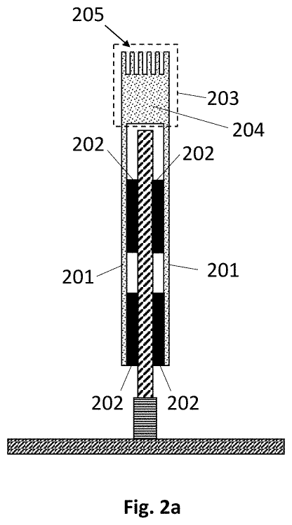

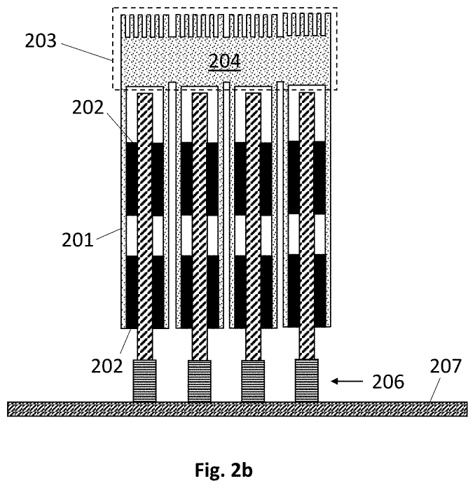

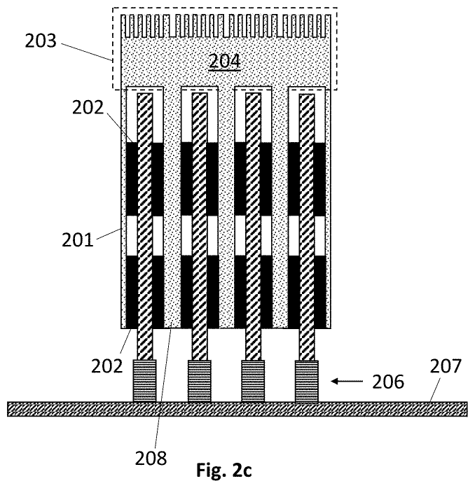

FIGS. 2a,b,c through 7a,b show more specific embodiments of various ones of the general approaches described just above or further features thereof.

FIGS. 2a, 2b and 2c show embodiments that respectively correspond to FIGS. 1a, 1b and 1c where the entire cooling assembly is formed from a same block of bulk material (e.g., a same block of metal (e.g., copper), a same block of a metal alloy (e.g., steel), etc.). In each of the embodiments of FIGS. 2a, 2b and 2c the heat spreaders merge into a mass of material that is the same material as the heat spreaders themselves, and where, the mass of material corresponds to the heat sink structure 204. Here, fins 205, or other surface area expanding structures, emerge from the heat sink structure 204 as structures formed in/on the surface of the heat sink structure's bulk material. In various embodiments, the cooling assembly is formed from a same bulk material, e.g., by milling and/or etching openings in the block to form the heat spreaders 201 and the fins 205, or moulding (e.g., die case moulding).

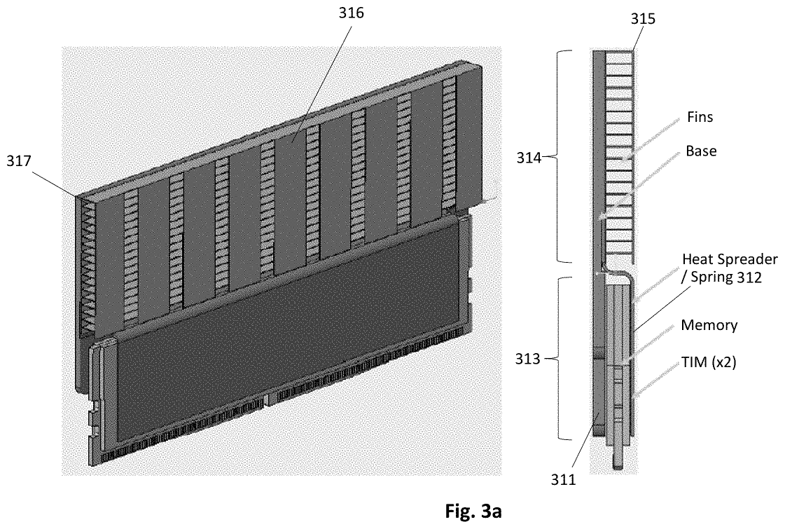

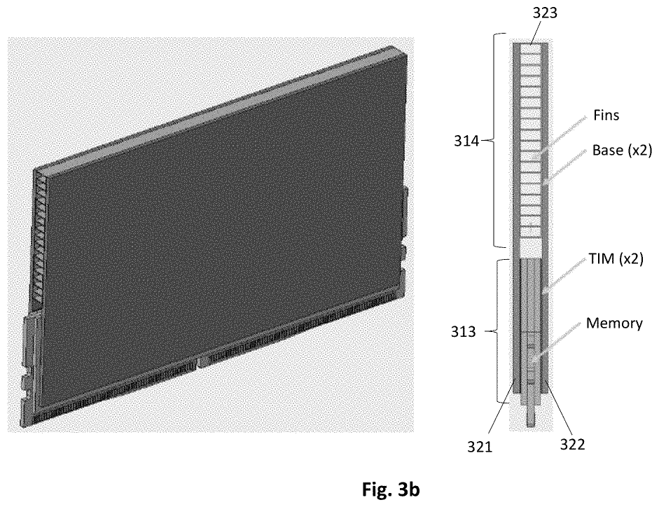

FIGS. 3a and 3b show embodiments where a same block of material can be used to form both a heat spreader component and a heat sink structure component but where, separate mechanical pieces are coupled together to form the complete cooling assembly.

As observed in a first embodiment of FIG. 3a, separate plates 311, 312 of metal (or metal alloy) are respectively fixed to each side of a DIMM. Both plates 311, 312 are formed, e.g., from their own separate piece of sheet metal. A first 311 of the plates, however, extends upward into the space above the DIMM such that the single plate 311 has both a heat spreading region 313 and a heat sink structure region 314.

The second plate 312 is bent akin to a leaf spring and is attached to the first plate 311. The leaf spring loading associated with the bending of the second plate 312 causes the second plate 312 to press against the side of the DIMM opposite the side that the first plate 311 is fixed to (the second plate 312 can also be mounted to its DIMM side in combination with or alternative to any spring loading applied by the bending of the second plate 312).

A third mechanical element 315 that includes a housing 316 for a shelfed stack of fins 317 is fixed to the heat sink portion 314 of the first plate 311 thereby forming the heat sink structure. The fins of the shelfed stack of fins 317 expand the surface area of the heat sink structure thereby lowering its thermal resistance with the ambient.

As observed in a second embodiment of FIG. 3b, both plates 321, 322 are extended to include both a heat spreading portion 313 and a heat sink portion 314. A third mechanical element 323 comprising a shelfed stack of fins is inserted between the heat sink structure portions of the plates 321, 322 to incorporate fins into the heat sink structure above the DIMM.

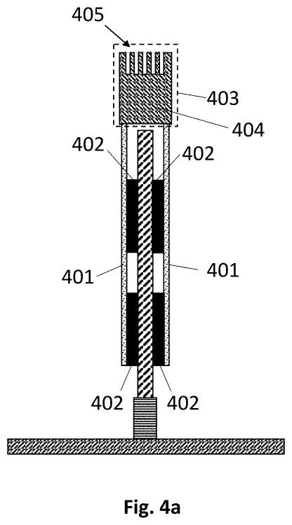

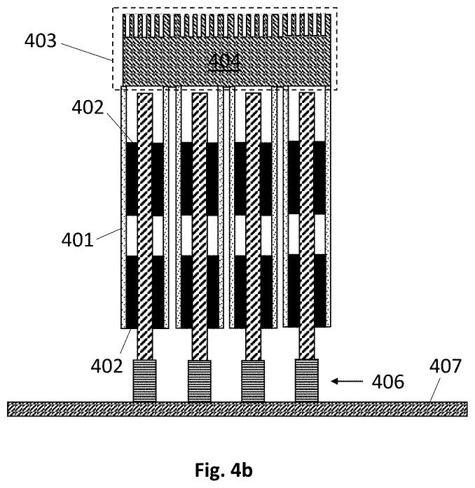

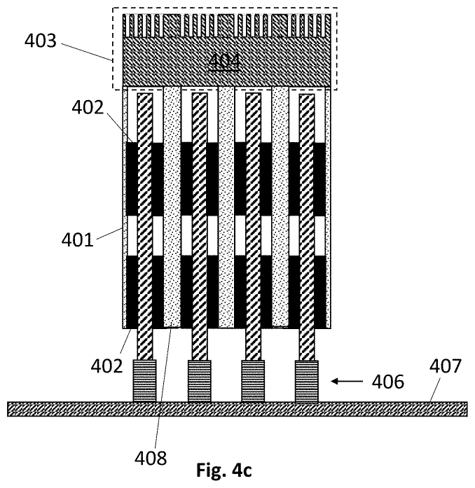

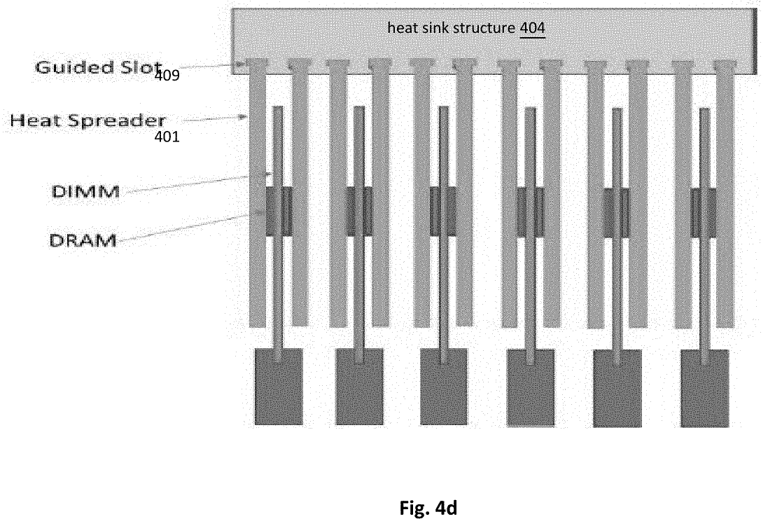

FIGS. 4a, 4b and 4c show another approach where the heat spreaders 401 are physically different structures than the heat sink structure 404. As such, the heat spreaders 401 are mechanically coupled to the heat sink structure 404 to form the overall cooling assembly.

FIG. 4d shows a particular approach for mechanically integrating (and thermally coupling) the heat spreaders 401 with the heat sink structure 404 for any of the embodiments of FIGS. 4a, 4b and 4c described above. As observed in FIG. 4g, the top edges of the heat spreaders 401 have tip extensions that fit into corresponding grooves 409 that are formed in the heat sink structure 404. Heat spreaders 401 are mechanically coupled to the heat sink structure 404 by sliding the edges of the heat spreaders 401 into the grooves 409 at a side of the heat sink structure 404 and sliding the heat spreaders into the heat sink structure 404 where the grooves 409 acts as sliding guides.

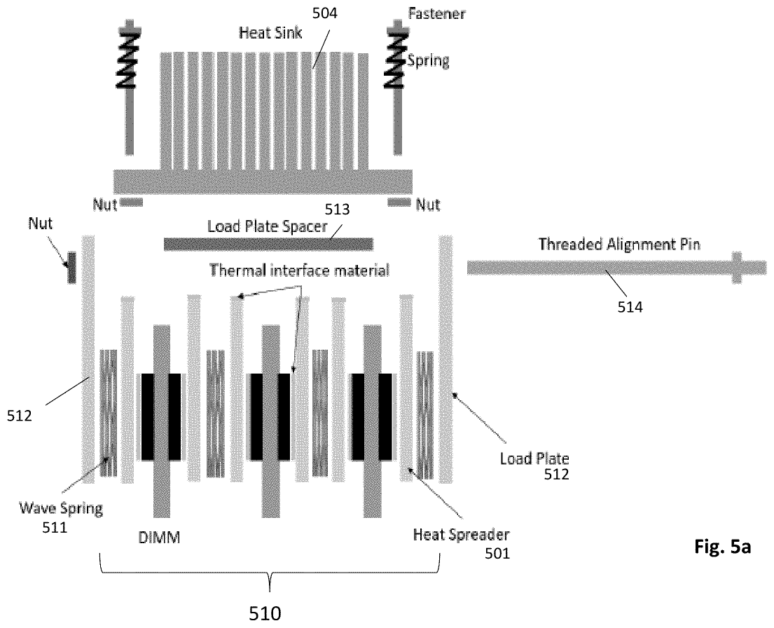

FIGS. 5a and 5b depict a more detailed embodiment for a cooling assembly like that of FIG. 4b (in which each DIMM side has a dedicated heat spreaders that is a separate mechanical element which is mechanically coupled to the heat sink structure).

FIG. 5a shows an exploded view. Here, a “stack” 510 of DIMMs is formed where each DIMM face has its own dedicated heat spreader 501 and a spring 511 placed on each heat spreader 501. The DIMM stack 510 is then compressed between a pair of loading plates 512 with a spacer 513 in between. The spacer 513, in the particular embodiment of FIGS. 5a and 5b is composed of a pair of rods 513 on opposite ends of the DIMM stack that are inserted through holes in the heat sink fins and then compressed between the loading plates 512.

The spacer 513 prevents the loading plates 512 from being compressed more than is appropriate for the set of DIMMs. For example, the spacer 513 prevents the stacked DIMMs from being compressed such that the separation between neighboring DIMMs is less than the DIMM spacing afforded by the DIMM sockets that the DIMMs will plug into. In various embodiments, to help “set” the stack 510, the DIMMs are staged in sockets having the appropriate separation as part of the stacking process before the loading plates 511 are tightened against the spacer 513.

The loading plates 511 are tightened against the spacer 513 with tightening hardware 514, which, in the particular embodiment of FIGS. 5a and 5b, corresponds to an alignment pin 514 that is inserted within aligned through holes that are formed in both loading plates 511 and the spacer 513. Again, the spacer rods 513 are inserted within holes within the fins of the heat sink 504.

The alignment pin 514 has a bolt or pan head on one end that prevents the pin 514 from fully passing through its corresponding loading plate, and threads on the other end of the pin 514. A nut is threaded onto the threads, and, as the nut is threaded it approaches the head of the pin which has the effect of compressing the loading plates 511 toward one another. The loading plates 511 eventually press upon the spacer 513 which corresponds to the correct amount of compression being imparted to the DIMM stack 510 to set the appropriate DIMM spacing with the stack 510.

The heat sink structure 504 is mounted to the hardware that the compresses the loading plates against the spacer, which, in the particular embodiment of FIG. 5a, corresponds to the alignment pin 514. The top surfaces of the heat spreaders are thermally coupled to the underside of the heat sink structure 504. The completed structure is depicted in FIG. 5b. As depicted in FIG. 5b, the compression applied to the loading plates 511 is such that the heat sink structure 504 is mounted to the compression hardware 514 outside (rather than inside) the loading plates. In other embodiments, the heat sink structure 504 can be mounted to the compression hardware 514 inside the loading plates (above the DIMM stack 510) alternatively to or in combination with being mounted to the compression hardware 514 outside the loading plates 511.

The structure/approach of FIGs. 5a and 5b can be readily extended to an approach like that of FIG. 3c by having only one heat spreader between neighboring DIMMs.

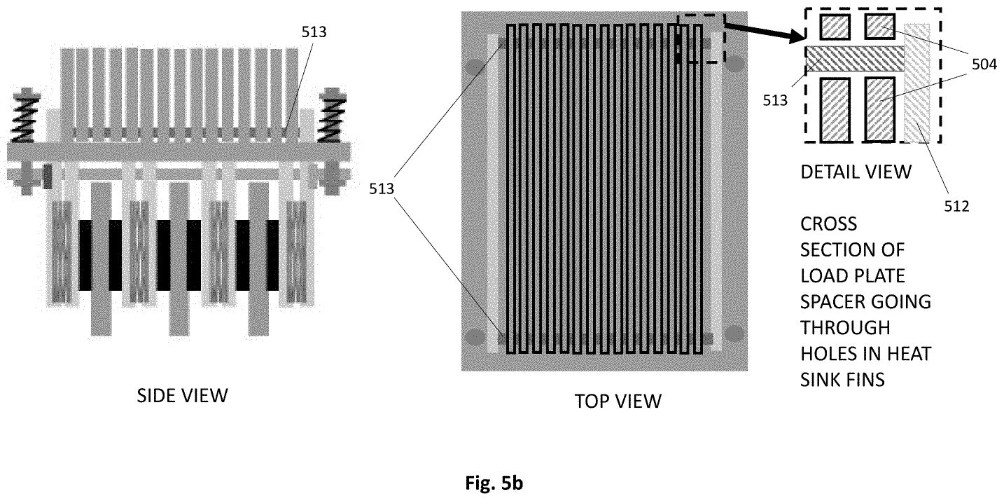

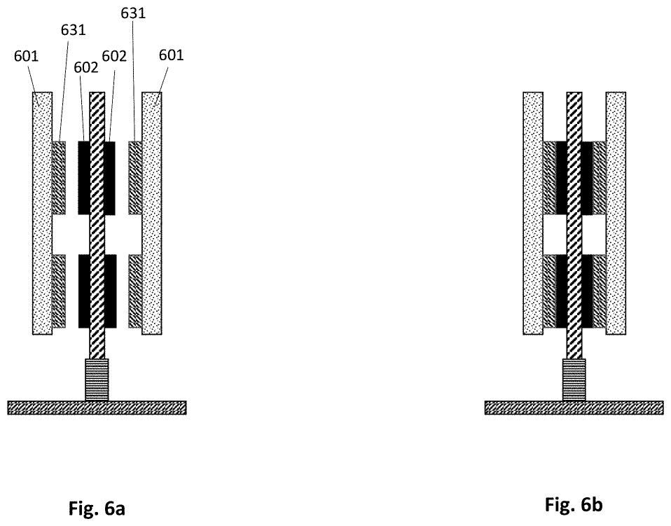

FIGS. 6a and 6b pertain to an additional feature that can be applied to any of the embodiments described above. Specifically, that thermally conductive pedestals 631 can emanate from the heat spreaders 601 to ensure compressive contact with the DIMM DRAMs 602. Here, FIG. 6a shows an initial situation during the construction of the cooling assembly when the heat spreaders 601 and their pedestals 631 have not yet been fully engaged with their respect DIMM. FIG. 6b shows the same hardware after the cooling assembly has been fully assembled and the heat spreaders 601 with pedestals 631 are engaged with their respect DIMM DRAMs 602. The pedestals 631 are akin to shim which consume any air gaps that might otherwise exist between the heat spreaders 601 and DIMM DRAMs 602.

According to one embodiment, the pedestals 631 are made from the same material as the heat spreader 601 (e.g., milled/etched from the same metal block as the heat spreader) such that they are homogenous protrusions from the surface of the heat spreader.

In another approach the pedestals 631 are separate components whose protrusion extent from the surface of the heat spreader 601 is adjustable. Here, the pedestals 631 can be spring loaded to the heat spreader 601 such that they push away from the heat spreader. For example, the side of a pedestal that faces the heat spreader 601 can be pressed against one or more wide, metal leaf springs that thermally couples the pedestal 631 to the heat spreader 601 and pushes the pedestal 631 away from the heat spreader 601.

One or more screws that mechanically couple the pedestal 631 to the heat spreader 601 are then tightened which presses the pedestal 631 toward the heat spreader 601. By turning the screw(s) an appropriate amount, the height of the pedestal 631 off the surface of the heat spreader 601 can be set to a specific distance of extension which, e.g., can correspond to the distance between the surface of the heat spreader 601 the DRAM chips 602 of the facing DIMM.

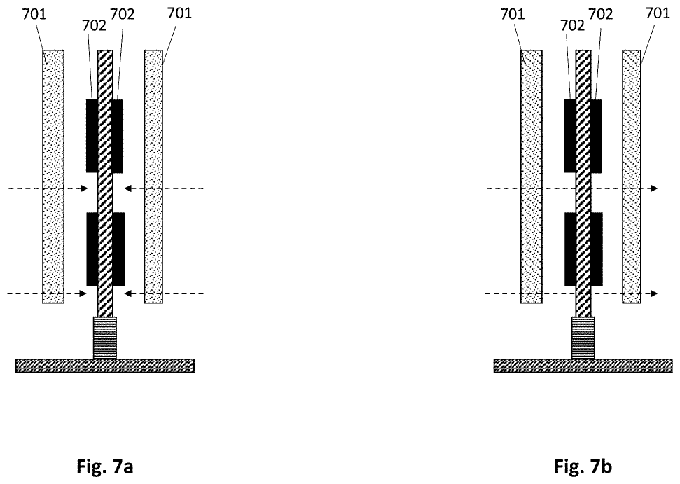

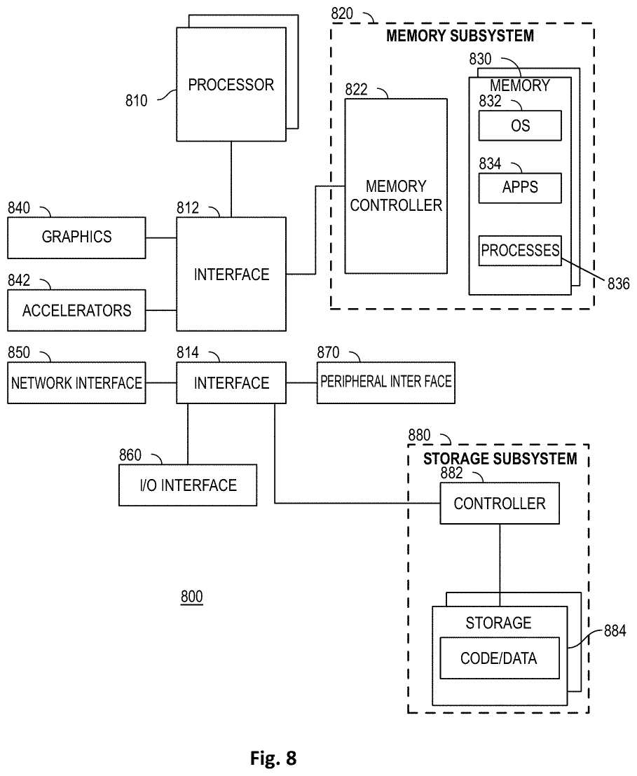

FIGS. 7a and 7b pertain to additional features that can be applied to any of the embodiments described above. In particular, screws, bolts, clamps, etc. (represented by dashed arrows in FIGS. 7a and 7b), spring loaded or otherwise, can be used to mount a heat spreader to its respective side of a DIMM. According to a first approach depicted in FIG. 7a, a heat spreader is mounted to hardware (not shown) located on the surface and/or backside of the DIMM whose DRAM chips the heat spreader is to be thermally coupled to. For example, screws are inserted through holes formed in the heat spreader, threaded into such hardware (e.g., stand-offs with threaded center holes) and tightened.

According to a second approach depicted in FIG. 7b, heat spreaders that are mounted to opposite sides of a same DIMM are mounted to one another through the DIMM. For example, a bolt is inserted into one heat spreader which passes through a through-hole in the DIMM and another aligned through hole in the other heat spreader. The bolt is then bolted down with a nut that is tightened at the other heat spreader which brings the heat spreaders toward one another and applies a compressive force to the DIMM between the pair of heat spreaders.

The hardware used to mount the heat spreaders to the DIMM and/or each other can be spring loaded such that a compressive force that drives the heat spreaders into the DIMM surfaces increases as the mounting hardware is tightened.

In any of the thermal couplings between separate components described above (e.g., DRAM to heat spreader, DRAM to pedestal, pedestal to heat spreader, heat spreader to heat sink component, heat sink component to fin component, etc.), the thermal coupling between the two components can be improved with thermal interface material being placed between the two components.

In even further embodiments, referring back to FIGS. 1a, 1b and 1c, the heat sink structure 104 is a more active cooling component such as a heat exchanger including but not limited to a cold plate or a vapor chamber.

In the case of a cold plate, the cold plate has a cool fluid inlet and a hot fluid outlet and a fluidic channel internal to the cold plate that thermally couples the inlet and outlet. Cool fluid enters the cool fluid inlet and flows through the fluidic channel. While running through the fluidic channel the fluid absorbs heat from the DIMM(s) and then exits the cold plate from the hot fluid outlet.

In the case of a vapor chamber, liquid inside a chamber boils from the heat that the liquid absorbs from the DIMM(s). The boiling activity removes heat from the liquid. Depending on implementation, the vapor chamber can be sealed, in which case, the vapor produced by the boiling condenses back to liquid within the chamber. The cooling of the vapor and corresponding condensation removes DIMM heat from the cooling assembly. The vapor chamber can further include thermal transfer enhancement structures (e.g., fins) to cool the chamber and induce more condensation.

In the case where the chamber is not sealed, the vapor exits the chamber from an outlet and is condensed back to a liquid by a heat exchanger that is external from the DIMM cooling assembly. The external heat exchanger causes condensation of the vapor which creates cooled liquid. The cooled liquid is returned to the vapor chamber through an inlet to the chamber.

Although embodiments above have emphasized DIMMs having DRAM memory chips, DIMMs having other kinds of memory chips, such as byte addressable non-volatile memory chips (e.g., Optane™ memory chips from Intel Corporation) can also implement the teachings above.

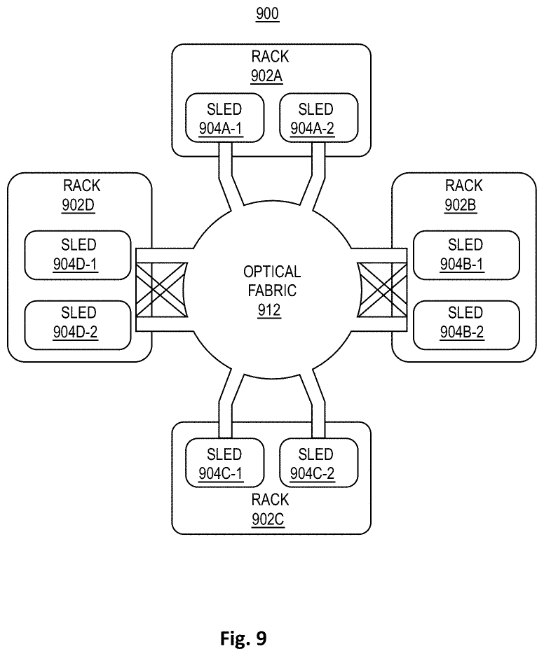

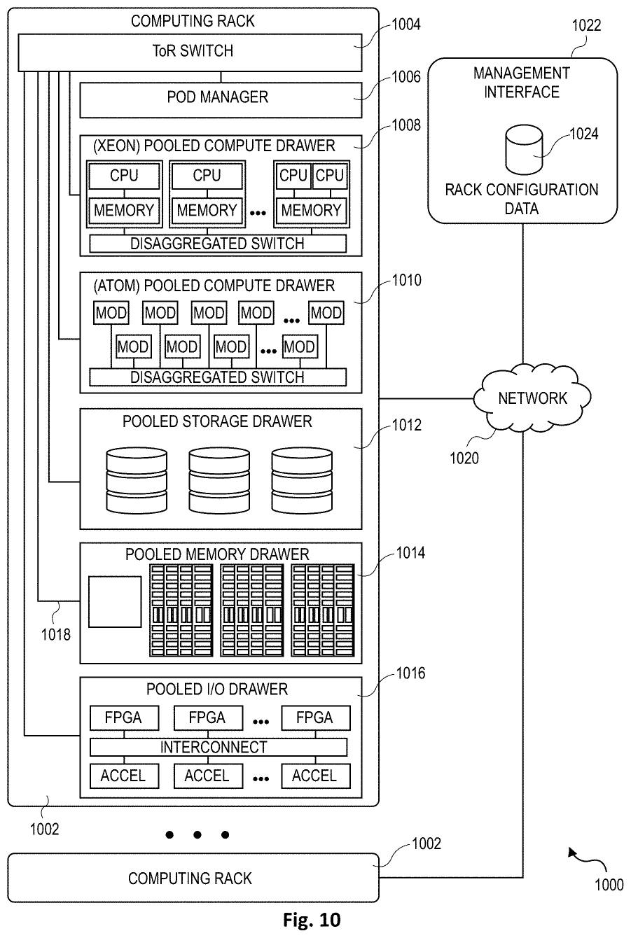

The following discussion concerning FIGS. 8, 9 and 10 are directed to systems, data centers and rack implementations, generally. FIG. 8 generally describes possible features of an electronic system that can include one or more DIMMs having a cooling assembly that is designed according to the teachings above. FIG. 9 describes possible features of a data center that can include such electronic systems. FIG. 10 describes possible features of a rack having one or more such electronic systems installed into it.

FIG. 8 depicts an example system. System 800 includes processor 810, which provides processing, operation management, and execution of instructions for system 800. Processor 810 can include any type of microprocessor, central processing unit (CPU), graphics processing unit (GPU), processing core, or other processing hardware to provide processing for system 800, or a combination of processors. Processor 810 controls the overall operation of system 800, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Certain systems also perform networking functions (e.g., packet header processing functions such as, to name a few, next nodal hop lookup, priority/flow lookup with corresponding queue entry, etc.), as a side function, or, as a point of emphasis (e.g., a networking switch or router). Such systems can include one or more network processors to perform such networking functions (e.g., in a pipelined fashion or otherwise).

In one example, system 800 includes interface 812 coupled to processor 810, which can represent a higher speed interface or a high throughput interface for system components that needs higher bandwidth connections, such as memory subsystem 820 or graphics interface components 840, or accelerators 842. Interface 812 represents an interface circuit, which can be a standalone component or integrated onto a processor die. Where present, graphics interface 840 interfaces to graphics components for providing a visual display to a user of system 800. In one example, graphics interface 840 can drive a high definition (HD) display that provides an output to a user. High definition can refer to a display having a pixel density of approximately 100 PPI (pixels per inch) or greater and can include formats such as full HD (e.g., 1080 p), retina displays, 4K (ultra-high definition or UHD), or others. In one example, the display can include a touchscreen display. In one example, graphics interface 840 generates a display based on data stored in memory 830 or based on operations executed by processor 810 or both. In one example, graphics interface 840 generates a display based on data stored in memory 830 or based on operations executed by processor 810 or both.

Accelerators 842 can be a fixed function offload engine that can be accessed or used by a processor 810. For example, an accelerator among accelerators 842 can provide compression (DC) capability, cryptography services such as public key encryption (PKE), cipher, hash/authentication capabilities, decryption, or other capabilities or services. In some embodiments, in addition or alternatively, an accelerator among accelerators 842 provides field select controller capabilities as described herein. In some cases, accelerators 842 can be integrated into a CPU socket (e.g., a connector to a motherboard or circuit board that includes a CPU and provides an electrical interface with the CPU). For example, accelerators 842 can include a single or multi-core processor, graphics processing unit, logical execution unit single or multi-level cache, functional units usable to independently execute programs or threads, application specific integrated circuits (ASICs), neural network processors (NNPs), “X” processing units (XPUs), programmable control logic circuitry, and programmable processing elements such as field programmable gate arrays (FPGAs). Accelerators 842 can provide multiple neural networks, processor cores, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 820 represents the main memory of system 800 and provides storage for code to be executed by processor 810, or data values to be used in executing a routine. Memory subsystem 820 can include one or more memory devices 830 such as read-only memory (ROM), flash memory, volatile memory, or a combination of such devices. Memory 830 stores and hosts, among other things, operating system (OS) 832 to provide a software platform for execution of instructions in system 800. Additionally, applications 834 can execute on the software platform of OS 832 from memory 830. Applications 834 represent programs that have their own operational logic to perform execution of one or more functions. Processes 836 represent agents or routines that provide auxiliary functions to OS 832 or one or more applications 834 or a combination. OS 832, applications 834, and processes 836 provide software functionality to provide functions for system 800. In one example, memory subsystem 820 includes memory controller 822, which is a memory controller to generate and issue commands to memory 830. It will be understood that memory controller 822 could be a physical part of processor 810 or a physical part of interface 812. For example, memory controller 822 can be an integrated memory controller, integrated onto a circuit with processor 810. In some examples, a system on chip (SOC or SoC) combines into one SoC package one or more of: processors, graphics, memory, memory controller, and Input/Output (I/O) control logic circuitry.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory), JESD235, originally published by JEDEC in October 2013, LPDDR5, HBM2 (HBM version 2), or others or combinations of memory technologies, and technologies based on derivatives or extensions of such specifications.

Such volatile memory devices can be placed on a DIMM and cooled with a cooling assembly designed according to the teachings above.

In various implementations, memory resources can be “pooled”. For example, the memory resources of memory modules installed on multiple cards, blades, systems, etc. (e.g., that are inserted into one or more racks) are made available as additional main memory capacity to CPUs and/or servers that need and/or request it. In such implementations, the primary purpose of the cards/blades/systems is to provide such additional main memory capacity. The cards/blades/systems are reachable to the CPUs/servers that use the memory resources through some kind of network infrastructure such as CXL, CAPI, etc.

The memory resources can also be tiered (different access times are attributed to different regions of memory), disaggregated (memory is a separate (e.g., rack pluggable) unit that is accessible to separate (e.g., rack pluggable) CPU units), and/or remote (e.g., memory is accessible over a network).

While not specifically illustrated, it will be understood that system 800 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect express (PCIe) bus, a HyperTransport or industry standard architecture (ISA) bus, a small computer system interface (SCSI) bus, Remote Direct Memory Access (RDMA), Internet Small Computer Systems Interface (iSCSI), NVM express (NVMe), Coherent Accelerator Interface (CXL), Coherent Accelerator Processor Interface (CAPI), Cache Coherent Interconnect for Accelerators (CCIX), Open Coherent Accelerator Processor (Open CAPI) or other specification developed by the Gen-z consortium, a universal serial bus (USB), or an Institute of Electrical and Electronics Engineers (IEEE) standard 1394 bus.

In one example, system 800 includes interface 814, which can be coupled to interface 812. In one example, interface 814 represents an interface circuit, which can include standalone components and integrated circuitry. In one example, multiple user interface components or peripheral components, or both, couple to interface 814. Network interface 850 provides system 800 the ability to communicate with remote devices (e.g., servers or other computing devices) over one or more networks. Network interface 850 can include an Ethernet adapter, wireless interconnection components, cellular network interconnection components, USB (universal serial bus), or other wired or wireless standards-based or proprietary interfaces. Network interface 850 can transmit data to a remote device, which can include sending data stored in memory. Network interface 850 can receive data from a remote device, which can include storing received data into memory. Various embodiments can be used in connection with network interface 850, processor 810, and memory subsystem 820.

In one example, system 800 includes one or more input/output (I/O) interface(s) 860. I/O interface 860 can include one or more interface components through which a user interacts with system 800 (e.g., audio, alphanumeric, tactile/touch, or other interfacing). Peripheral interface 870 can include any hardware interface not specifically mentioned above. Peripherals refer generally to devices that connect dependently to system 800. A dependent connection is one where system 800 provides the software platform or hardware platform or both on which operation executes, and with which a user interacts.

In one example, system 800 includes storage subsystem 880 to store data in a nonvolatile manner. In one example, in certain system implementations, at least certain components of storage 880 can overlap with components of memory subsystem 820. Storage subsystem 880 includes storage device(s) 884, which can be or include any conventional medium for storing large amounts of data in a nonvolatile manner, such as one or more magnetic, solid state, or optical based disks, or a combination. Storage 884 holds code or instructions and data in a persistent state (e.g., the value is retained despite interruption of power to system 800). Storage 884 can be generically considered to be a “memory,” although memory 830 is typically the executing or operating memory to provide instructions to processor 810. Whereas storage 884 is nonvolatile, memory 830 can include volatile memory (e.g., the value or state of the data is indeterminate if power is interrupted to system 800). In one example, storage subsystem 880 includes controller 882 to interface with storage 884. In one example controller 882 is a physical part of interface 814 or processor 810 or can include circuits in both processor 810 and interface 814.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

Such non-volatile memory devices can be placed on a DIMM and cooled with a cooling assembly designed according to the teachings above.

A power source (not depicted) provides power to the components of system 800. More specifically, power source typically interfaces to one or multiple power supplies in system 800 to provide power to the components of system 800. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 800 can be implemented as a disaggregated computing system. For example, the system 800 can be implemented with interconnected compute sleds of processors, memories, storages, network interfaces, and other components. High speed interconnects can be used such as PCIe, Ethernet, or optical interconnects (or a combination thereof). For example, the sleds can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Although a computer is largely described by the above discussion of FIG. 8, other types of systems to which the above described invention can be applied and are also partially or wholly described by FIG. 8 are communication systems such as routers, switches and base stations.

FIG. 9 depicts an example of a data center. Various embodiments can be used in or with the data center of FIG. 9. As shown in FIG. 9, data center 900 may include an optical fabric 912. Optical fabric 912 may generally include a combination of optical signaling media (such as optical cabling) and optical switching infrastructure via which any particular sled in data center 900 can send signals to (and receive signals from) the other sleds in data center 900. However, optical, wireless, and/or electrical signals can be transmitted using fabric 912. The signaling connectivity that optical fabric 912 provides to any given sled may include connectivity both to other sleds in a same rack and sleds in other racks.

Data center 900 includes four racks 902A to 902D and racks 902A to 902D house respective pairs of sleds 904A-1 and 904A-2, 904B-1 and 904B-2, 904C-1 and 904C-2, and 904D-1 and 904D-2. Thus, in this example, data center 900 includes a total of eight sleds. Optical fabric 912 can provide sled signaling connectivity with one or more of the seven other sleds. For example, via optical fabric 912, sled 904A-1 in rack 902A may possess signaling connectivity with sled 904A-2 in rack 902A, as well as the six other sleds 904B-1, 904B-2, 904C-1, 904C-2, 904D-1, and 904D-2 that are distributed among the other racks 902B, 902C, and 902D of data center 900. The embodiments are not limited to this example. For example, fabric 912 can provide optical and/or electrical signaling.

FIG. 10 depicts an environment 1000 that includes multiple computing racks 1002, each including a Top of Rack (ToR) switch 1004, a pod manager 1006, and a plurality of pooled system drawers. Generally, the pooled system drawers may include pooled compute drawers and pooled storage drawers to, e.g., effect a disaggregated computing system. Optionally, the pooled system drawers may also include pooled memory drawers and pooled Input/Output (I/O) drawers. In the illustrated embodiment the pooled system drawers include an INTEL® XEON® pooled computer drawer 1008, and INTEL® ATOM™ pooled compute drawer 1010, a pooled storage drawer 1012, a pooled memory drawer 1014, and a pooled I/O drawer 1016. Each of the pooled system drawers is connected to ToR switch 1004 via a high-speed link 1018, such as a 40 Gigabit/second (Gb/s) or 100 Gb/s Ethernet link or an 100+Gb/s Silicon Photonics (SiPh) optical link. In one embodiment high-speed link 1018 comprises an 600 Gb/s SiPh optical link.

Again, the drawers can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Multiple of the computing racks 1000 may be interconnected via their ToR switches 1004 (e.g., to a pod-level switch or data center switch), as illustrated by connections to a network 1020. In some embodiments, groups of computing racks 1002 are managed as separate pods via pod manager(s) 1006. In one embodiment, a single pod manager is used to manage all of the racks in the pod. Alternatively, distributed pod managers may be used for pod management operations. RSD environment 1000 further includes a management interface 1022 that is used to manage various aspects of the RSD environment. This includes managing rack configuration, with corresponding parameters stored as rack configuration data 1024.

Any of the systems, data centers or racks discussed above, apart from being integrated in a typical data center, can also be implemented in other environments such as within a bay station, or other micro-data center, e.g., at the edge of a network.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some examples may be implemented using or as an article of manufacture or at least one computer-readable medium. A computer-readable medium may include a non-transitory storage medium to store program code. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the program code implements various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

To the extent any of the teachings above can be embodied in a semiconductor chip, a description of a circuit design of the semiconductor chip for eventual targeting toward a semiconductor manufacturing process can take the form of various formats such as a (e.g., VHDL or Verilog) register transfer level (RTL) circuit description, a gate level circuit description, a transistor level circuit description or mask description or various combinations thereof. Such circuit descriptions, sometimes referred to as “IP Cores”, are commonly embodied on one or more computer readable storage media (such as one or more CD-ROMs or other type of storage technology) and provided to and/or otherwise processed by and/or for a circuit design synthesis tool and/or mask generation tool. Such circuit descriptions may also be embedded with program code to be processed by a computer that implements the circuit design synthesis tool and/or mask generation tool.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences may also be performed according to alternative embodiments. Furthermore, additional sequences may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

1. A dual in-line memory module (DIMM) cooling apparatus, comprising:
a) a first heat spreader to be thermally coupled to respective memory chips of a first side of the DIMM;
b) a second heat spreader to be thermally coupled to respective memory chips of a second side of the DIMM;
c) a heat sink element, the heat sink element positioned such that the DIMM is to be between the heat sink element and a connector that the DIMM is to plug into, the heat sink element having thermal transfer structures to facilitate thermal transfer between the heat sink element and the heat sink element's ambient.

2. The DIMM cooling apparatus of claim 1 wherein the first heat spreader, the second heat spreader, and the heat sink element are formed from a same bulk material.

3. The DIMM cooling apparatus of claim 1 wherein a portion of the heat sink element and the first heat spreader are formed from a same bulk material.

4. The DIMM cooling apparatus of claim 3 wherein another portion of the heat sink element and the second heat spreader are formed from a same bulk material.

5. The DIMM cooling apparatus of claim 1 wherein the first heat spreader, the second heat spreader, and the heat sink element are separate mechanical components of the DIMM cooling assembly.

6. The DIMM cooling apparatus of claim 5 wherein the cooling assembly is to be mounted to multiple DIMMs including the DIMM, the heat sink element to receive additional heat from additional heat spreaders that are thermally coupled to those of the multiple DIMMs other than the DIMM.

7. The DIMM cooling apparatus of claim 1 wherein the thermal transfer structures comprise fins.

8. The DIMM cooling apparatus of claim 1 further comprising one or more of:
respective pedestals emanating from the first and second heat spreaders, the pedestals to be coupled between the respective memory chips of the first and second heat spreaders and the first and second heat spreaders, respectively;
grooves within the heat sink element that respective tips of the first and second heat spreaders slide into.

9. An apparatus, comprising:
a) a DIMM;
b) a first heat spreader that is thermally coupled to respective memory chips of a first side of the DIMM;
c) a second heat spreader that is thermally coupled to respective memory chips of a second side of the DIMM;
d) a heat sink element, the heat sink element positioned such that the DIMM is to be between the heat sink element and a connector that the DIMM is to plug into, the heat sink element to receive heat from the first and second heat spreaders, the heat sink element having thermal transfer structures to facilitate thermal transfer between the heat sink element and the heat sink element's ambient.

10. The apparatus of claim 9 wherein the first heat spreader, the second heat spreader, and the heat sink element are formed from a same bulk material.

11. The apparatus of claim 9 wherein a portion of the heat sink element and the first heat spreader are formed from a same bulk material.

12. The apparatus of claim 11 wherein another portion of the heat sink element and the second heat spreader are formed from a same bulk material.

13. The apparatus of claim 9 wherein the first heat spreader, the second heat spreader, and the heat sink element are separate mechanical components of the DIMM cooling assembly.

14. The apparatus of claim 13 wherein the cooling assembly is to be mounted to multiple DIMMs including the DIMM, the heat sink element to receive additional heat from additional heat spreaders that are thermally coupled to those of the multiple DIMMs other than the DIMM.

15. The apparatus of claim 9 wherein the thermal transfer structures comprise fins.

16. The apparatus of claim 9 further comprising one or more of:
respective pedestals emanating from the first and second heat spreaders, the pedestals coupled between the respective memory chips of the first and second heat spreaders and the first and second heat spreaders, respectively;
grooves within the heat sink element that respective tips of the first and second heat spreaders are inserted within.

17. A data center, comprising:
a) a plurality of racks;
b) a plurality of electronic systems installed into the racks;
c) one or more networks that communicatively couple the plurality of electronic systems;
d) a DIMM within one of the electronic systems, a cooling assembly coupled to the DIMM, the cooling assembly comprising i), ii), and iii) below:
i) a first heat spreader that is thermally coupled to respective memory chips of a first side of the DIMM;
ii) a second heat spreader that is thermally coupled to respective memory chips of a second side of the DIMM;
iii) a heat sink element, the heat sink element positioned such that the DIMM is to be between the heat sink element and a connector that the DIMM is to plug into, the heat sink element having thermal structures to facilitate thermal transfer between the heat sink element and the heat sink element's ambient.

18. The apparatus of claim 17 wherein the first heat spreader, the second heat spreader, and the heat sink element are formed from a same bulk material.

19. The apparatus of claim 17 wherein a portion of the heat sink element and the first heat spreader are formed from a same bulk material.

20. The apparatus of claim 19 wherein another portion of the heat sink element and the second heat spreader are formed from a same bulk material.
